(19) United States
(12) Patent Application Publication
(10) Pub. No.: US 2008/0225588 A1
(43) Pub. Date: Sep. 18, 2008

(54) Capacitorless DRAM and method of manufacturing and operating the same

(75) Inventors: Young-gu Jin, Hwaseong-si (KR); Jai-kwang Shin, Anyang-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/007,738

(22) Filed: Jan. 15, 2008

(30) Foreign Application Priority Data
Mar. 13, 2007 (KR) 10-2007-0024678

(51) Int. Cl. G11C 11/34; H01L 29/78; H01L 21/336

(52) U.S. Cl. 365/182; 257/331; 438/272; 257/E29.262; 257/E21.41

(57) ABSTRACT

Provided are a capacitorless dynamic random access memory (DRAM) and a method of manufacturing and operating the capacitorless DRAM. The capacitorless DRAM includes a substrate having a first dopant region formed on the upper part thereof, a first protrusion unit formed on the substrate, a first gate and a second gate formed on the substrate on both sides of the first protrusion unit, having a height lower than the first protrusion unit, and an insulating material layer interposed between the substrate and the first and second gates and between the first protrusion unit and the first and second gates, wherein a second dopant region is formed on the upper part of the first protrusion unit.

### CROSS-REFERENCE TO RELATED PATENT APPLICATION

This application claims the benefit of Korean Patent Application No. 10-2007-0024678, filed on Mar. 13, 2007, in the Korean Intellectual Property Office, the disclosure of which is incorporated herein in its entirety by reference.

### BACKGROUND OF THE INVENTION

1. Field of the Invention

The present invention relates to a semiconductor device and a method of manufacturing and operating the same, and more particularly, to a capacitorless dynamic random access memory (DRAM) that can increase integration density by preventing a short channel effect and can effectively prevent the degradation of refresh characteristics, and a method of manufacturing and operating the same.

2. Description of the Related Art

A memory cell of a conventional dynamic random access memory (DRAM) has a 1T/1C structure in which one transistor and one capacitor are included. A cell area of the conventional DRAM is generally 8F² (F: feature size). Recently, a DRAM having the cell area of 6F² has been disclosed.

Since the conventional DRAM includes a transistor and a capacitor, it is very difficult to reduce the cell area of the conventional DRAM to 4F² or less.

In consideration of scale down, a DRAM that can store data using only the transistor without the capacitor, i.e., a capacitorless 1T DRAM has been proposed. The capacitorless 1T DRAM has an electrically floated channel.

FIGS. 1A and 1B are cross-sectional views of a conventional capacitorless DRAM and a method of operating the conventional capacitorless DRAM.

Referring to FIGS. 1A and 1B, a gate 110 is formed on a silicon on insulator (SOI) substrate 100. The SOI substrate 100 has a structure in which a first silicon layer 10, an oxide layer 20, and a second silicon layer 30 are sequentially stacked, and the gate 110 has a structure in which a gate insulating layer 40 and a gate conductive layer 50 are sequentially stacked. A source 30a and a drain 30b are formed in the second silicon layer 30 on both sides of the gate 110. A floating channel body 30c that is electrically separated from the first silicon layer 10 is formed to a thickness of approximately 150 nm between the source 30a and the drain 30b.

As depicted in FIG. 1A, when voltages of 0.6V, 0V, and 2.3V are respectively applied to the gate conductive layer 50, the source 30a, and the drain 30b, electrons migrate from the source 30a to the drain 30b through the floating channel body 30c. In this process, electron-hole pairs are generated by electron collision in the floating channel body 30c. At this point, the holes cannot leave the floating channel body 30c but accumulate in the floating channel body 30c. The holes are called excess holes 5. A state when the excess holes 5 accumulate in the floating channel body 30c is a first state.

As depicted in FIG. 1B, when voltages of 0.6V, 0V, and −2.3V are respectively applied to the gate conductive layer 50, the source 30a, and the drain 30b, a forward bias is applied between the floating channel body 30c and the drain 30b. At this point, the excess holes 5 are removed from the floating channel body 30c, and electrons 7 excessively accumulate in the floating channel body 30c. A state when the electrons excessively accumulate in the floating channel body 30c is a second state.

Since the floating channel body 30c has different resistances in the first and second state, the first and second states respectively can correspond to data ‘1’ and ‘0’ ′.

However, since the conventional capacitorless DRAM is a planar type, scale down can be difficult due to the following reasons. When the length of the floating channel body 30c is reduced, the doping concentration in the floating channel body 30c must be increased in order to ensure a threshold voltage. However, this case can cause an increase in the junction leakage current between the floating channel body 30c and the source 30a and the drain 30b, thereby reducing refresh characteristics of the DRAM. Also, when the length of the floating channel body 30c is reduced below the critical length, an interference, that is, a short channel effect occurs between the source 30a and the drain 30b, thereby degrading operational characteristics of the DRAM.

### SUMMARY OF THE INVENTION

In order to solve the above and/or other problems, the present invention provides a capacitorless dynamic random access memory (DRAM) that has a high integration density and can effectively prevent the degradation of refresh characteristics and a short channel effect.

The present invention also provides a method of manufacturing a capacitorless DRAM.

The present invention also provides a method of operating a capacitorless DRAM.

According to an aspect of the present invention, there is provided a capacitorless DRAM (dynamic random access memory) including a substrate having a first dopant region formed on the upper part thereof; a first protrusion unit formed on the substrate; a first gate and a second gate formed on the substrate on both sides of the first protrusion unit, having a height lower than the first protrusion unit; and an insulating material layer interposed between the substrate and the first and second gates and between the first protrusion unit and the first and second gates, wherein a second dopant region is formed on the upper part of the first protrusion unit.

The capacitorless DRAM may further include a second protrusion unit and a third gate sequentially formed beside the first gate which are located opposite to the first protrusion unit, and an insulating material layer interposed between the substrate and the third gate and between the second protrusion unit and the first and third gates identical to the insulating material layer interposed between the substrate and the first and second gates and between the first protrusion unit and the first and second gates, and the upper part of the second protrusion unit may a dopant region identical to the second dopant region.

The first and second protrusion units may commonly contact a bit line.

The first and second protrusion units may contact different bit lines.

The first protrusion unit may have a width smaller than the first and second gates.

One of the first and second gates may be a front gate, and the other may be a back gate.

One of the first and second gates may be a front gate, the other may be a back gate, and the third gate may be identical to the second gate.

The substrate and the first protrusion unit may be one body.

The substrate, the first protrusion unit, and the second protrusion unit may be one body.

According to another aspect of the present invention, there is provided a method of manufacturing a capacitorless DRAM, including forming a first protrusion unit and a second protrusion unit which are apart from each other, are parallel to each other and face each other on a substrate; forming a first insulating layer on the substrate and the first and second protrusion units; doping the upper part of the substrate and the upper parts of the first and second protrusion units; forming gates having a height lower than the first and second protrusion units on the first insulating layer beside the first and second protrusion units; removing the first insulating layer from the upper parts of the first and second protrusion units; separating the first and second protrusion units into cell units by patterning the first and second protrusion units; and forming a second insulating layer on the substrate exposed by the patterning of the first and second protrusion units, the gates, and the first and second protrusion units.

The first and second insulating layers may be formed of oxides.

The forming of the first and second protrusion units may include sequentially forming a first oxide layer, a first nitride layer, and a second oxide layer on a substrate; forming a mask layer on the second oxide layer; etching the second oxide layer, the first nitride layer, the first oxide layer, and a portion of the thickness of the substrate on both sides of the mask layer; removing the mask layer; forming a third oxide layer that covers the surfaces exposed by the etching on the substrate and the second oxide layer; etching the third oxide layer and the second oxide layer until the first nitride layer is exposed; forming a trench that exposes the substrate by removing the first nitride layer and the first oxide layer; forming second nitride layers on inner walls of the trench; etching the substrate using the second nitride layers as etch masks; and removing the second nitride layers and third oxide layer.

The method may further include doping the substrate with a dopant prior to sequentially forming the first oxide layer, the first nitride layer, and the second oxide layer.

The method may further include exposing the upper parts of the first and second protrusion units by etching the second insulating layer after forming the second insulating layer.

According to another aspect of the present invention, there is provided a method of manufacturing a capacitorless DRAM, including forming first and second supporting insulating layers which are separated from each other and face each other on a substrate; forming a first protrusion unit and a second protrusion unit respectively on the surfaces of the first and second supporting insulating layers facing each other; forming a first insulating layer on the substrate, the first and second supporting insulating layers, and the first and second protrusion units; firstly doping the upper part of the substrate between the first and second protrusion units and the upper parts of the first and second protrusion units; forming a first gate having a height lower than the first and second protrusion units on the first insulating layer between the first and second protrusion units; removing the first insulating layer and the first and second supporting insulating layers; forming a second insulating layer on the substrate, the first and second protrusion units, and the first gate; secondly doping the upper part of the substrate and the upper parts of the first and second protrusion units; forming a second gate on the second insulating layer beside the first protrusion unit and forming a third gate on the second insulating layer beside the second protrusion unit; removing the second insulating layer from the upper parts of the first and second protrusion units; separating the first and second protrusion units into cell units by patterning the first and second protrusion units; and forming a third insulating layer on the substrate exposed by patterning the first and second protrusion units, the first through third gates, and the first and second protrusion units.

The forming of the first and second supporting insulating layers and the first and second protrusion units may include sequentially forming a first oxide layer, a first nitride layer, and a second oxide layer on a substrate; forming a mask layer on the second oxide layer; etching the second oxide layer, the first nitride layer, the first oxide layer, and a portion of the thickness of the substrate on both sides of the mask layer; removing the mask layer; forming a third oxide layer that covers the surfaces exposed by the etching on the substrate and the second oxide layer; etching the third oxide layer and the second oxide layer until the first nitride layer is exposed; forming a trench that exposes the substrate by removing the first nitride layer and the first oxide layer; forming second nitride layers on inner walls of the trench; etching the substrate using the second nitride layers as etch masks; and removing the second nitride layers.

The method may further include doping the substrate prior to sequentially forming the first oxide layer, the first nitride layer, and the second oxide layer.

The method may further include exposing the upper parts of the first and second protrusion units by etching the third insulating layer after forming the third insulating layer.

According to another aspect of the present invention, there is provided a method of operating a capacitorless DRAM that includes a substrate having a first dopant region formed on the upper part thereof; a first protrusion unit formed on the substrate; a first gate and a second gate formed on the substrate on both sides of the first protrusion unit, having a height lower than the first protrusion unit; and an insulating material layer interposed between the substrate and the first and second gates and between the first protrusion unit and the first and second gates, wherein a second dopant region is formed on the upper part of the first protrusion unit, the method comprising applying voltages respectively to the first and second dopant regions and the first and second gates.

The voltage may be one of a data writing voltage, a data holding voltage, a data reading voltage, and a data erasing voltage.

The capacitorless DRAM may further include a second protrusion unit and a third gate sequentially arranged beside the first gate which are located opposite to the first protrusion unit, and an insulating material layer formed between the substrate and the third gate and between the second protrusion unit and the first and third gates identical to the insulating material layer interposed between the substrate and the first and second gates and between the first protrusion unit and the first and second gates, and the upper part of the second protrusion unit is a third dopant region identical to the second dopant region.

Voltages may respectively be applied to the first and third dopant regions and the first and third gates and the voltage may be one of a data writing voltage, a data reading voltage, and a data erasing voltage.

Voltages may respectively be applied to the first through third dopant regions and the first through third gates and the voltage may be one of a data writing voltage, a data reading voltage, and a data erasing voltage.

The first and second protrusion units may commonly contact a bit line.

The first and second protrusion units may individually contact bit lines different from each other.

The use of the present invention can prevent the short channel effect and the degradation of refresh characteristics and can increase the integration density of the capacitorless DRAM.

### BRIEF DESCRIPTION OF THE DRAWINGS

The above and other features and advantages of the present invention will become more apparent by describing in detail exemplary embodiments thereof with reference to the attached drawings in which:

FIGS. 1A and 1B respectively are cross-sectional views of the structure of a conventional capacitorless dynamic random access memory (DRAM) and a method of operating the conventional capacitorless DRAM;

FIG. 2 is a perspective view of a capacitorless DRAM according to an embodiment of the present invention;

FIG. 3 is a cross-sectional view taken along the line I-I′ of FIG. 2, according to an embodiment of the present invention;

FIG. 4 is a plan view of the capacitorless DRAM illustrated in FIG. 2, according to an embodiment of the present invention;

FIG. 5 is a graph showing current-voltage characteristics of a capacitorless DRAM according to an embodiment of the present invention;

FIGS. 6A through 6N are perspective views illustrating a method of manufacturing a capacitorless DRAM according to an embodiment of the present invention; and

FIGS. 7A through 7J are perspective views illustrating a method of manufacturing a capacitorless DRAM according to another embodiment of the present invention.

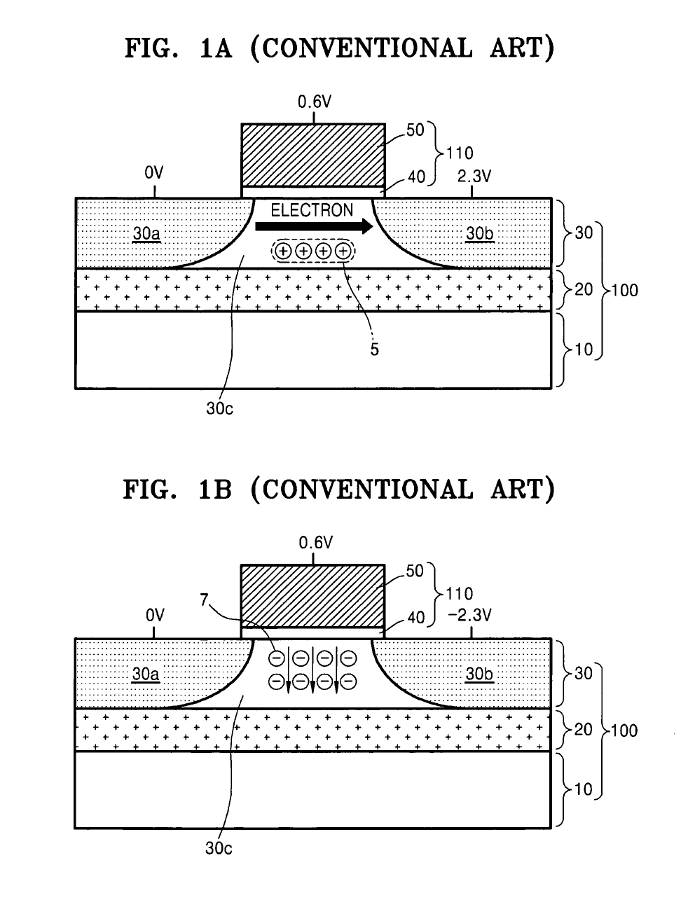

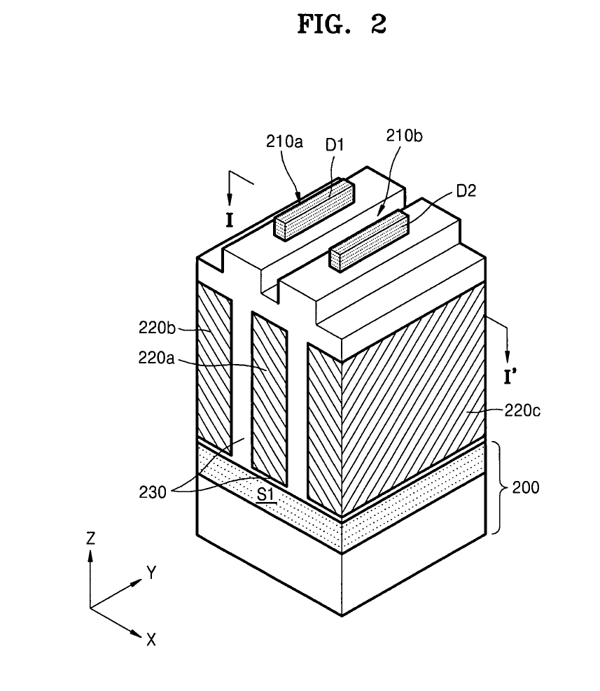

### DETAILED DESCRIPTION OF THE INVENTION

A capacitorless dynamic random access memory (DRAM) according to the present invention and a method of manufacturing and operating the same will now be described more fully with reference to the accompanying drawings in which exemplary embodiments of the invention are shown. In the drawings, the thicknesses of layers and regions are exaggerated for clarity, and like reference numerals refer to like elements.

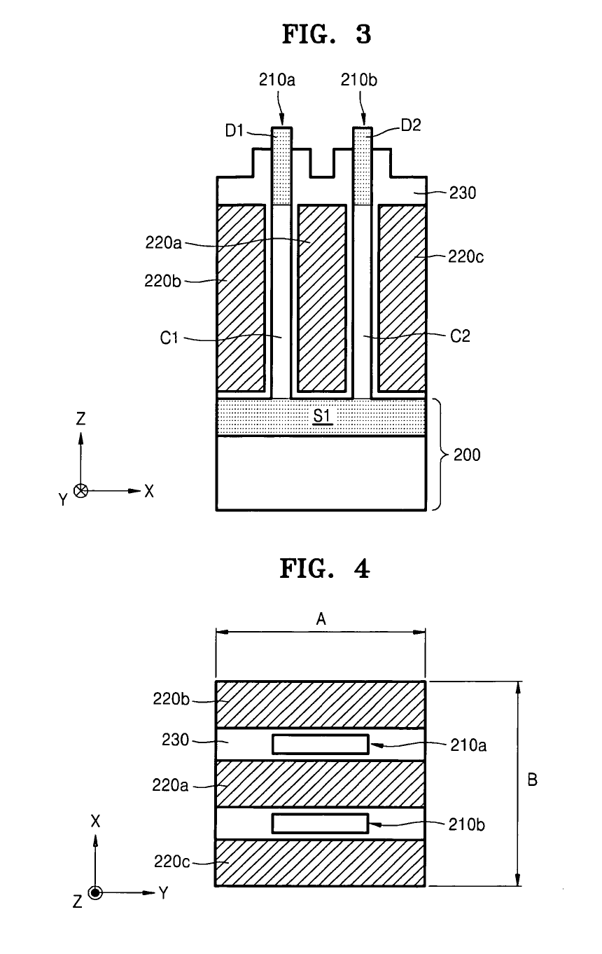

FIG. 2 is a perspective view of a capacitorless DRAM according to an embodiment of the present invention. FIG. 3 is a cross-sectional view taken along line I-I′ of FIG. 2, and FIG. 4 is a plan view of the capacitorless DRAM illustrated in FIG. 2.

Referring to FIGS. 2 through 4, first and second protrusion units 210a and 210b protrude on a substrate 200 such as a silicon substrate in a direction perpendicular (a Z axis direction) to the substrate 200. The first and second protrusion units 210a and 210b are formed by protruding portions of the substrate 200. The first and second protrusion units 210a and 210b are parallel to each other, separated from each other, and have a smaller width in a Y direction than that of the substrate 200. A first gate 220a is formed on the substrate 200 between the first and second protrusion units 210a and 210b, and second and third gates 220b and 220c are formed parallel to the first gate 220a on both ends of the substrate 200 in an X axis direction. Thus, the first protrusion unit 210a is located between the first and second gates 220a and 220b, and the second protrusion unit 210b is located between the first and third gates 220a and 220c. The first through third gates 220a through 220c have a line shape parallel to the Y direction, and have a height lower than that of the first and second protrusion units 210a and 210b. The first through third gates 220a through 220c can be formed of at least one of a metal and a polysilicon. An insulating material layer 230 is formed between the first through third gates 220a through 220c and the substrate 200, between the first through third gates 220a through 220c and the first and second protrusion units 210a and 210b, and on the first through third gates 220a through 220c. The insulating material layer 230 is formed lower than the first and second protrusion units 210a and 210b, and thus, the upper ends of the first and second protrusion units 210a and 210b can be exposed.

The upper part of the substrate 200 can be a source S1 doped with a first conductive type dopant, and the upper parts of the first and second protrusion units 210a and 210b can be first and second drains D1 and D2 doped with the first conductive type dopant. For example, the source S1 and the first and second drains D1 and D2 can also be N⁺ regions doped with an N type dopant. The first protrusion unit 210a between the source S1 and the first drain D1 is a first channel body C1, and the second protrusion unit 210b between the source S1 and the second drain D2 is a second channel body C2. The first and second channel bodies C1 and C2 can be an intrinsic semiconductor region or a region where a second conductive type dopant is doped. For example, the first and second channel bodies C1 and C2 can be undoped silicon regions or P-type silicon regions where a P-type dopant is doped with a low concentration. The first and second channel bodies C1 and C2 can have the same height as the first gate 220a.

The second and third gates 220b and 220c are front gates, and the first gate 220a is a back gate, or vice versa.

As described above, the capacitorless DRAM according to the present embodiment has a dual gate structure in which the front gate and the back gate are formed in both sides of the first and second channel bodies C1 and C2. Even though the first and second channel bodies C1 and C2 are intrinsic semiconductors and the thicknesses of the first and second channel bodies C1 and C2 are thin, the movement of electrons and holes in the first and second channel bodies C1 and C2 can be readily controlled by the front gate and the back gate. For example, excess holes can accumulate in the first channel body C1 or the excess holes accumulated in the first channel body C1 can be removed by respectively applying a predetermined voltage to the first gate 220a, the second gate 220b, the first drain D1, and the source S1. A process of accumulating the excess holes in the first channel body C1 can be divided into first and second mechanisms. The first mechanism is the generation of electron-hole pairs by the collision of electrons, and the second mechanism is the generation of holes due to electron tunneling. The first and second mechanisms also occur in the second channel body C2. A state when the excess holes accumulate in the first channel body C1 can be regarded as data ‘1’′ being recorded. The same thing can be applied to the second channel body C2. Another state when the excess holes are removed from the first channel body C1, that is, when electrons are excessively present in the first channel body C1 can be regarded as data ‘0’′ being recorded. The same thing can be applied to the second channel body C2. Therefore, when the excess holes accumulate in the first and second channel bodies C1 and C2, it can be regarded as two bit data ‘11’′ being recorded. According to the data recorded in the first channel body C1, the electric resistance of the first channel body C1 varies. Accordingly, data recorded in the first channel body C1 can be read by measuring the electric resistance in the first channel body C1. This is also true in the second channel body C2.

The first and second drains D1 and D2 can be connected to one common bit line (not shown) or individually connected to two bit lines (not shown). In the case when the first and second drains D1 and D2 are connected to one common bit line, the first and second protrusion units 210a and 210b and the first through third gates 220a through 220c form one cell. In this case, the first and second channel bodies C1 and C2 function as one data storage. In the case when the first and second drains D1 and D2 are individually connected to two bit lines, the first and second protrusion units 210a and 210b and the first through third gates 220a through 220c form two cells. That is, the first protrusion unit 210a and the first and second gates 220a and 220b form one cell, and the second protrusion unit 21b and the first and third gates 220a and 220c form another cell. In this case, first and second channel bodies C1 and C2 respectively function as individual data storages.

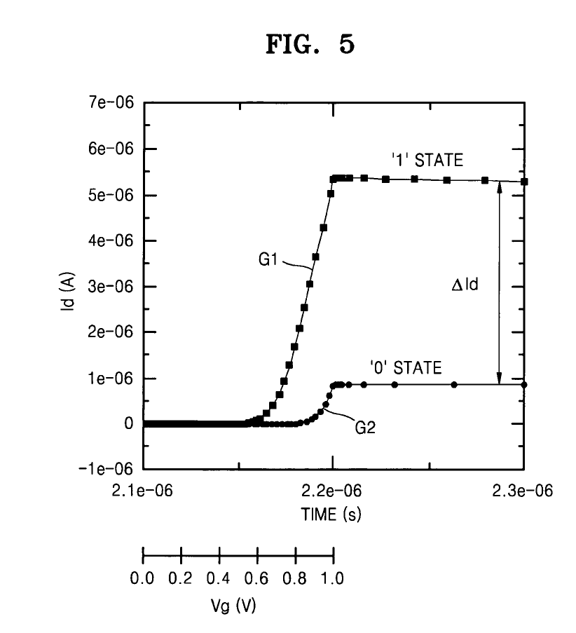

FIG. 5 is a graph showing current-voltage characteristics of a capacitorless DRAM according to an embodiment of the present invention.

The results illustrated in FIG. 5 are obtained by performing a simulation with respect to the capacitorless DRAM illustrated in FIG. 2.

More specifically, the results illustrated in FIG. 5 are the current-voltage characteristics of a cell formed by the first protrusion unit 210a and the first and second gates 220a and 220b. In the above simulation, the thicknesses and heights of the first and second protrusion units 210a and 210b respectively are 10 nm and 100 nm, and the heights of the first through third gates 220a through 220c are 63 nm. In FIG. 5, the first horizontal axis indicates time s, the second horizontal axis indicates a voltage Vg applied to the second gate 220b (hereinafter, a front gate voltage Vg), and the vertical axis indicates a current Id of the first drain D1 (hereinafter, a drain current Id).

In FIG. 5, a first curve G1 shows the current-voltage characteristics of the capacitorless DRAM in a state when the excess holes accumulate in the first channel body C1, that is, data ‘1’′ is recorded (hereinafter, a ‘1’′ state), and a second curve G2 shows the current-voltage characteristics of the capacitorless DRAM in a state when the excess holes are removed from the first channel body C1, that is, data ‘0’ is recorded (hereinafter, a ‘0’ state).

In order to make the first channel body C1 be in the ‘1’′ state, the front gate voltage Vg, a voltage being applied to the first gate 220a (hereinafter, a back gate voltage Vb), a voltage being applied to the first drain D1 (hereinafter, a drain voltage Vd), and a source voltage Vs of respectively −1.0V, −1.0V, 1.0V, and 0V can be applied. Also, in order to make the first channel body C1 be in the ‘0’′ state, the front gate voltage Vg, the back gate voltage Vb, the drain voltage Vd, and the source voltage Vs of respectively 1.5V, −1.0V, −0.5V, and 0V can be applied. The mechanism used for this writing operation follows the second mechanism described above. In order to make the first channel body C1 be in the ‘1’′ state using the first mechanism described above, the front gate voltage Vg, the back gate voltage Vb, the drain voltage Vd, and the source voltage Vs of respectively 1.0V, −0.7V, 1.5V, and 0V can be applied. Also, in order to make the first channel body C1 be in the ‘0’′ state using the first mechanism described above, the front gate voltage Vg, the back gate voltage Vb, the drain voltage Vd, and the source voltage Vs of respectively 1.0V, −0.7V, −1.0V, and 0V can be applied.

As depicted in FIG. 5, the variations of drain current Id are measured by increasing the front gate voltage Vg from 0V to 1.0V. Here, the back gate voltage Vb of −1.0V is applied.

Referring to FIG. 5, as the front gate voltage Vg increases beyond 0.6V, the difference between the drain current Id in the ‘1’′ state and the drain current in the ‘0’′ state becomes large. Also, when the front gate voltage Vg increases beyond approximately 0.8V, it can be seen that current sensing for a reading operation is possible. The drain voltage Vd for the reading operation can be approximately 0.1V.

Tables 1 and 2 below summarize the front gate voltage Vg, the back gate voltage Vb, the drain voltage Vd, and the source voltage Vs for making the first channel body C1 be in the ‘1’ state and the ‘0’′ state. The front gate voltage Vg, the back gate voltage Vb, the drain voltage Vd, and the source voltage Vs in Table 1 are obtained by using the first mechanism, and those in Table 2 are obtained by using the second mechanism. In Tables 1 and 2, ‘Hold’ indicates voltages required for maintaining the state of the first channel body C1, and ‘Read’ indicates voltages required for reading the state of the first channel body C1. Data erasing can be performed using the same principle as for the data writing. For example, data recorded in the first channel body C1 can be erased by changing the state of the first channel body C1 from the ‘1’ state to the ‘0’′ state.

TABLE 1

| Item | write “1” | write “0” | hold | read |
|---|---|---|---|---|
| Vg | 1.0 | 1.0 | 0 | 0.8~1.0 |
| Vb | −0.7 | −0.7 | −0.7 | −0.7 |
| Vd | 1.5 | −1.0 | 0 | 0.2 |
| Vs | 0 | 0 | 0 | 0 |

TABLE 2

| Item | write “1” | write “0” | hold | read |
|---|---|---|---|---|
| Vg | −1.0 | 1.5 | 0 | 1.0 |
| Vb | −1.0 | −1.0 | −1.0 | −1.0 |
| Vd | 1.0 | −0.5 | 0 | 0.1 |
| Vs | 0 | 0 | 0 | 0 |

In the capacitorless DRAM illustrated in FIG. 2, when the first and second protrusion units 210a and 210b and the first through third gates 220a through 220c form one cell, since the reading sensing is performed from the first and second channel bodies C1 and C2 where the same data are recorded, the drain current difference ΔId, that is, the sensing margin illustrated in FIG. 5 with respect to one cell can be doubled. This sensing margin is larger than that of the conventional capacitorless DRAM.

When the first and second protrusion units 210a and 210b respectively belong to different cells, the integration density of the capacitorless DRAM is doubled compared to the case when the first and second protrusion units 210a and 210b belong to the same cell. According to a method of manufacturing the capacitorless DRAM, which will be described later, since a gap between an outer surface of the first protrusion unit 210a and an outer surface of the second protrusion unit 210b can be 1F (F: feature size), A and B illustrated in FIG. 4 can respectively be 2F. Therefore, when the first and second protrusion units 210a and 210b belong to the same cell, an area of a unit cell can be 4F², and when the first and second protrusion units 210a and 210b respectively belong to difference cells, an area of the unit cell can be 2F².

Also, in the capacitorless DRAM according to the present embodiment, the first and second channel bodies C1 and C2 and the first and second drains D1 and D2 are perpendicular to the substrate 200. Therefore, although the scale of the capacitorless DRAM is reduced so as to increase the number of cells per unit area, the length of the channel can be maintained long. Thus, the capacitorless DRAM according to the present invention can have improved operation characteristics by preventing the short channel effect and the degradation of refresh characteristics.

In FIGS. 2 through 4, the capacitorless DRAM has a structure in which one cell or two cells are included, and the capacitorless DRAM according to the present invention can have a two dimensional (2D) array of the cell illustrated in FIG. 2. For example, if the first protrusion unit 210a is formed on a side of the second gate 220b, a plurality of protrusion units and a plurality of gates can further be included alternately on the other side of the second gate 220b.

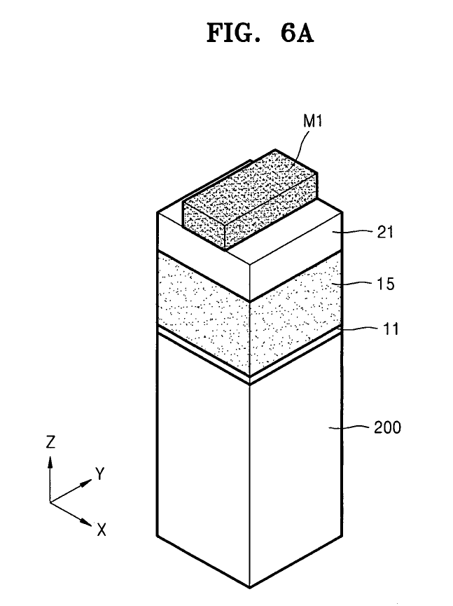

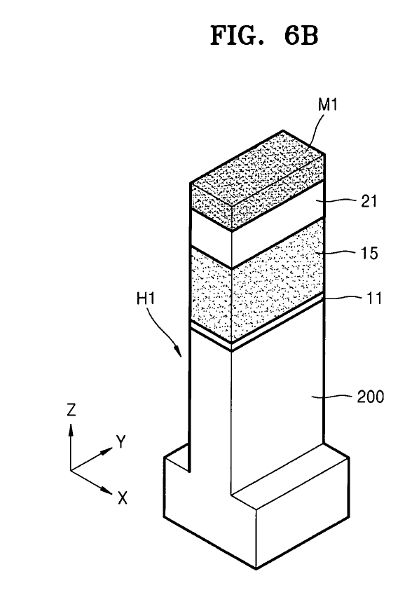

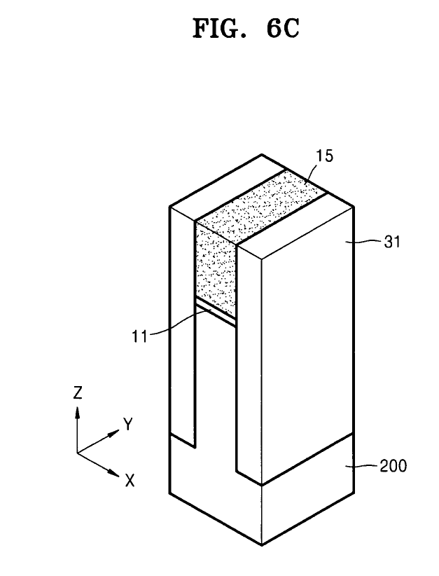

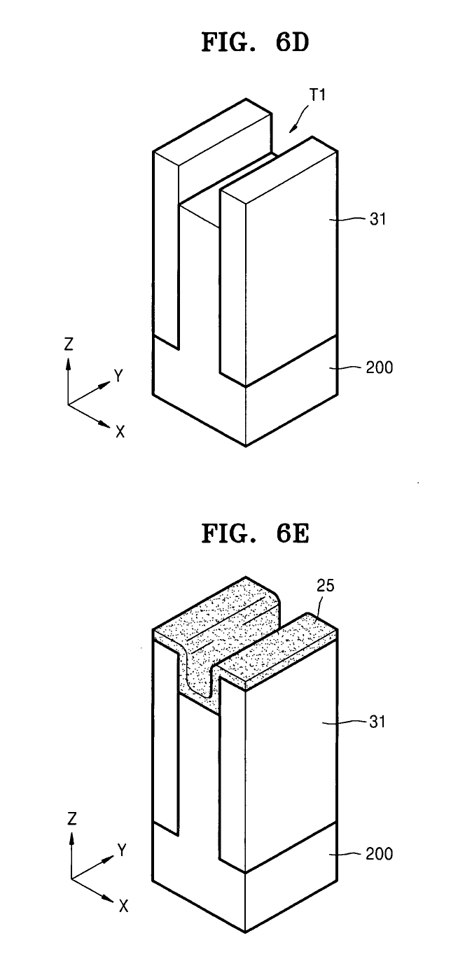

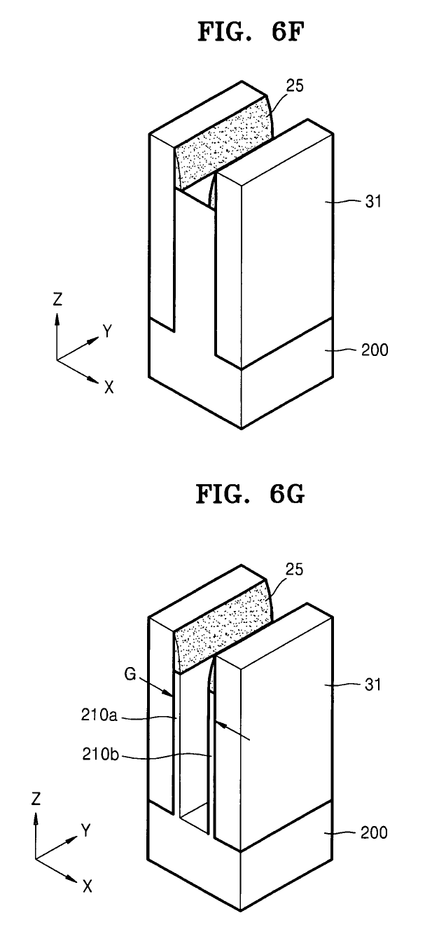

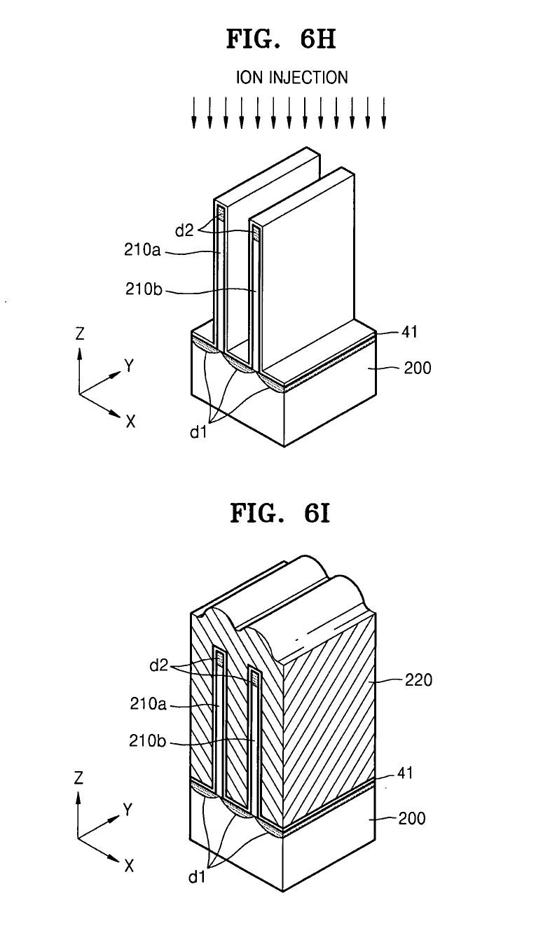

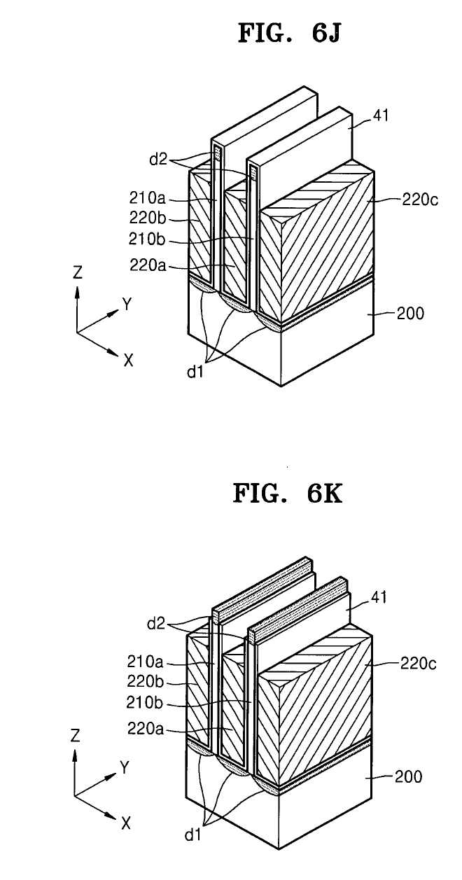

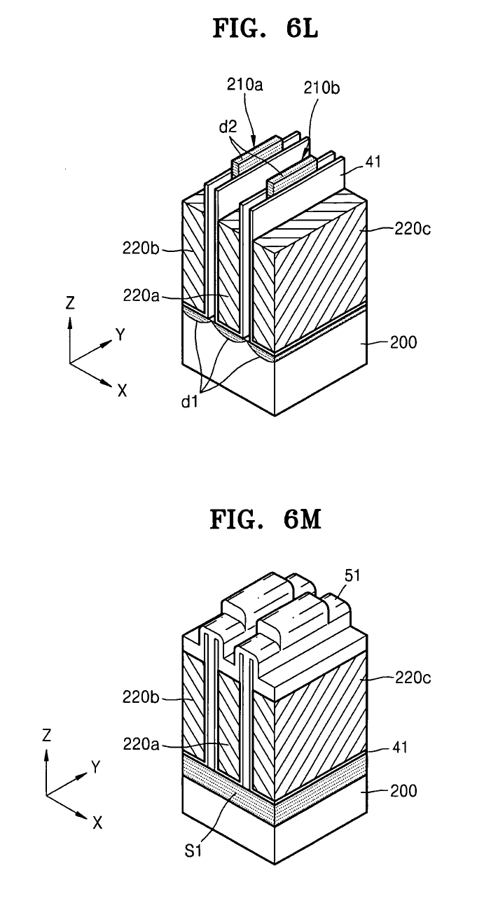

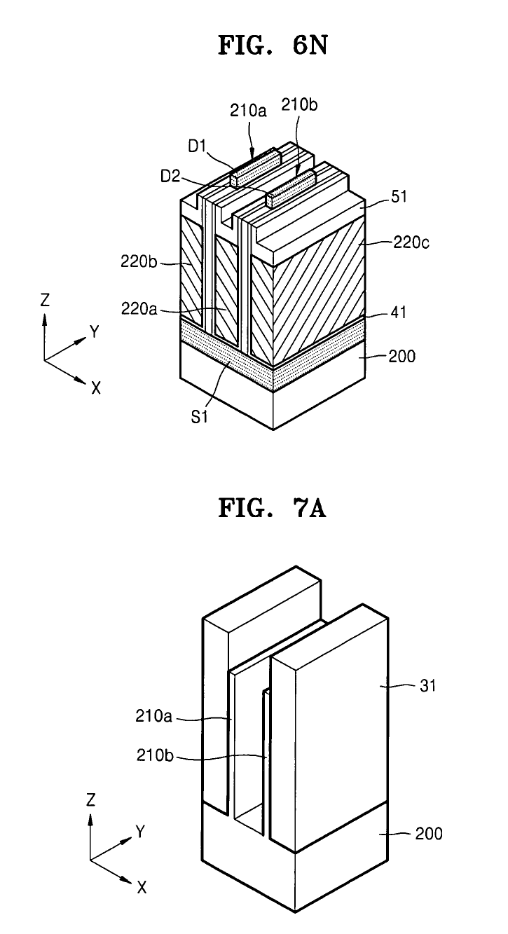

FIGS. 6A through 6N are perspective views illustrating a method of manufacturing a capacitorless DRAM according to an embodiment of the present invention.

Referring to FIG. 6A, a first oxide layer 11, a first nitride layer 15, and a second oxide layer 21 are sequentially formed on a substrate 200. The first oxide layer 11 can be a buffer layer for forming the first nitride layer 15. Next, a mask layer M1 that exposes both ends of the second oxide layer 21 in an X direction is formed on the second oxide layer 21.

Referring to FIG. 6B, grooves H1 are formed by sequentially etching the second oxide layer 21, the first nitride layer 15, the first oxide layer 11, and a portion of the thickness of the substrate 200 around the mask layer M1. The grooves H1 can be line-shaped grooves parallel to each other in a Y axis direction, and can be repeatedly arranged at a equal distance in the X axis direction. After the grooves H1 are formed, the mask layer M1 is removed.

Referring to FIG. 6C, a third oxide layer 31 that buries the grooves H1 is formed on the second oxide layer 21. Afterwards, the third oxide layer 31 and the second oxide layer 21 are polished until the first nitride layer 15 is exposed using a chemical mechanical polishing (CMP) method. Next, as depicted in FIG. 6D, a trench T1 that exposes the substrate 200 is formed by removing the first nitride layer 15 and the first oxide layer 11. In this process, a portion of the third oxide layer 31 can also be removed.

Referring to FIG. 6E, a second nitride layer 25 is conformably formed on the surface of the trench T1 and the third oxide layer 31. The second nitride layer 25 is anisotropically etched. Due to the anisotropical etching characteristics, the second nitride layer 25 formed on the upper surface of the trench T1 and on the upper surface of the third oxide layer 31 is removed, and as depicted in FIG. 6F, the second nitride layer 25 remains on inner walls of the trench T1.

Referring to FIG. 6F, the substrate 200 is etched using the second nitride layer 25 remaining after the anisotropical etching as an etch mask. As a result, as depicted in FIG. 6G, the first and second protrusion units 210a and 210b which are separated from each other and parallel to each other are formed on the substrate 200. A gap G between the outer surface of the first protrusion unit 210a and the outer surface of the second protrusion unit 210b (hereinafter, an outer gap G between the first and second protrusion units 210a and 210b) can be 1F as the width of the mask M1 as depicted in FIG. 6A. Accordingly, the outer gap G between the first and second protrusion units 210a and 210b can be a few tens to a few hundreds of nm. The thickness of the first and second protrusion units 210a and 210b can be a few to a few hundreds of nm, for example, approximately 10 nm.

Next, referring to FIG. 6H, after the second nitride layer 25 and the third oxide layer 31 are removed from the product illustrated in FIG. 6G, a fourth oxide layer 41 is conformably formed on the substrate 200 and the first and second protrusion units 210a and 210b. Afterwards, the upper part of the substrate 200 and the upper parts of the first and second protrusion units 210a and 210b are doped with a first conductive type dopant. As a result, a first doped region d1 is formed on the upper part of the substrate 200, and a second doped regions d2 are formed on the upper parts of the first and second protrusion units 210a and 210b. At this point, since the widths of the first and second protrusion units 210a and 210b are narrow, the doping concentration of the second doped regions d2 can be lower than the doping concentration of the first doped region d1. In order to avoid the doping concentration difference between the first doped region d1 and the second doped regions d2, the upper part of the substrate 200 can be doped with the first conductive type dopant prior to forming the first oxide layer 11 (refer to FIG. 6A). In this way, the upper parts of the first and second protrusion units 210a and 210b are doped twice with the first conductive type dopant, and thus, the doping concentrations of the first doped region d1 and the second doped regions d2 can be identical.

Referring to FIG. 61, a gate material layer 220 that covers the first and second protrusion units 210a and 210b is formed on the fourth oxide layer 41.

Referring to FIG. 6J, the gate material layer 220 is polished until the fourth oxide layer 41 is exposed using a CMP method. Next, the height of the gate material layer 220 is reduced so as to be lower than the first and second protrusion units 210a and 210b by anisotropically etching the gate material layer 220. As a result, the first through third gates 220a through 220c are formed on both sides of the first and second protrusion units 210a and 210b. The first gate 220a is formed between the first and second protrusion units 210a and 210b.

Referring to FIG. 6K, the fourth oxide layer 41 is removed from the upper parts of the first and second protrusion units 210a and 210b by anisotropically etching the fourth oxide layer 41. As a result, the second dopant regions d2 are exposed.

Referring to FIG. 6L, the substrate 200 is exposed by etching both ends (in the Y axis direction) of the first and second protrusion units 210a and 210b. The etching can be performed by using a lithography process.

Referring to FIG. 6M, a fifth oxide layer 51 is formed on the substrate 200 exposed by removing the both ends of the first and second protrusion units 210a and 210b, on the first through third gates 220a through 220c, and on the first and second protrusion units 210a and 210b.

Next, an annealing process is performed with respect to the first and second dopant regions d1 and d2 so as to activate the first and second dopant regions d1 and d2. Due to the annealing, the dopants of the first and second dopant regions d1 and d2 are diffused. At this point, the dopants in the first dopant region d1 diffuse into the substrate 200 below the first and second protrusion units 210a and 210b. The first dopant region d1 activated as described above can be a source S1, and the second dopant regions d2 can be drains. The drain formed on the first protrusion unit 210a is a first drain D1, and the drain formed on the second protrusion unit 210b is a second drain D2. The annealing process can be performed in any manner after the first and second dopant regions d1 and d2 are formed (refer to FIG. 6H).

Referring to FIG. 6N, the upper ends of the first and second protrusion units 210a and 210b are exposed by etching the fifth oxide layer 51. Afterwards, although not shown, a bit line or bit lines that commonly contact or individually contact the first and second protrusion units 210a and 210b can be formed.

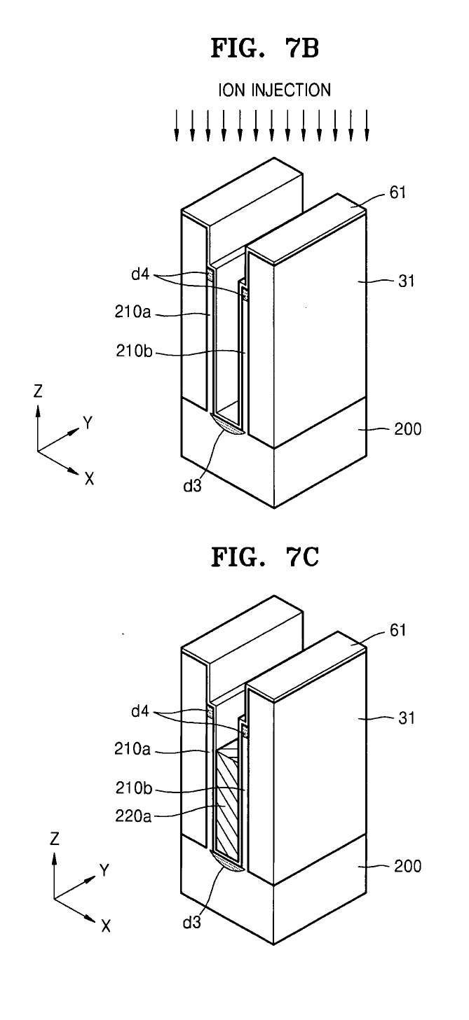

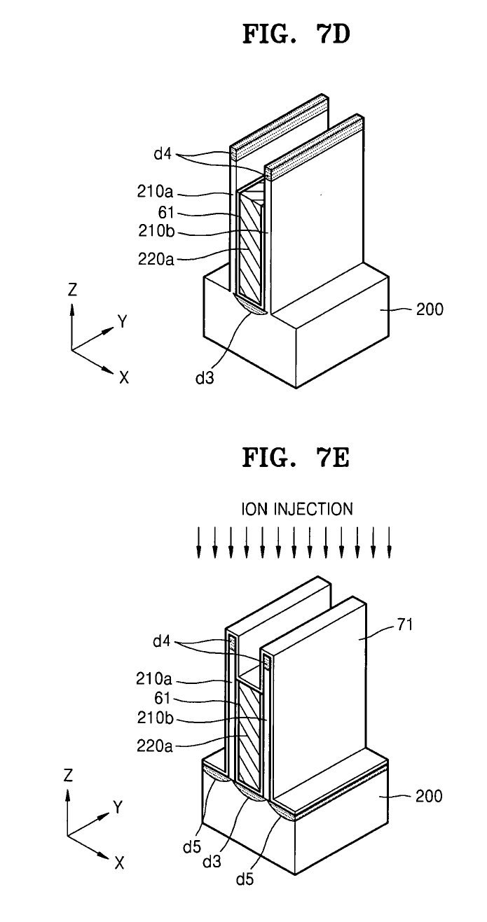

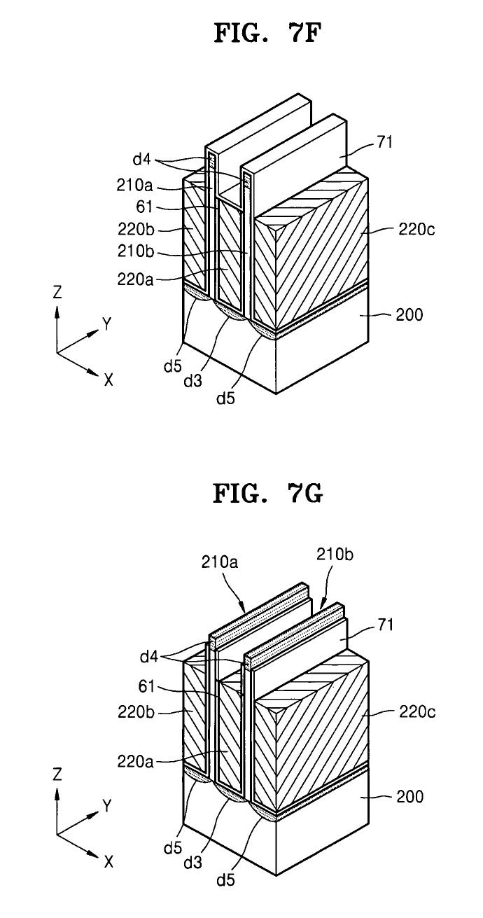

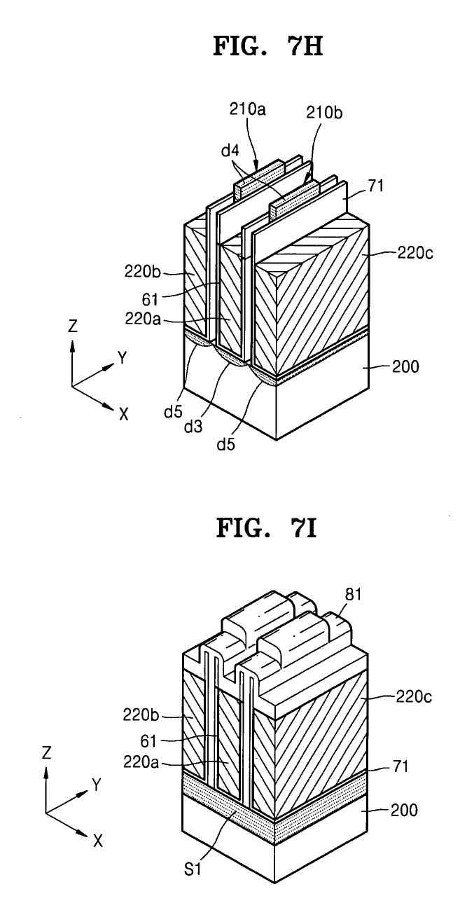

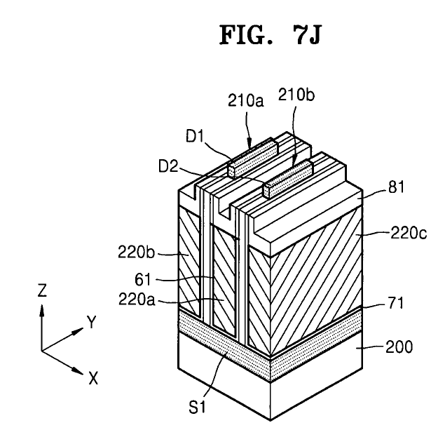

FIGS. 7A through 7J are perspective views illustrating a method of manufacturing a capacitorless DRAM according to another embodiment of the present invention. The method of manufacturing a capacitorless DRAM according to the present embodiment is a modified form of the method of manufacturing a capacitorless DRAM described with reference to FIGS. 6A through 6N. Therefore, the processes described with reference to FIGS. 6A through 6J in the previous embodiment are identical to the present embodiment, and thus, the description thereof will not be repeated, but subsequent processes will be described.

Referring to FIG. 7A, the second nitride layer 25 is removed from the resultant product illustrated in FIG. 6G. The third oxide layer 31, which is beside the first and second protrusion units 210a and 210b, supports the first and second protrusion units 210a and 210b.

Referring to FIG. 7B, a sixth oxide layer 61 is conformably formed on the substrate 200, the first and second protrusion units 210a and 210b, and the third oxide layer 31. Next, the upper part of the substrate 200 between the first and second protrusion units 210a and 210b and the upper parts of the first and second protrusion units 210a and 210b are doped with the first conductive type dopant. As a result, a third dopant region d3 is formed on the upper part of the substrate 200, and fourth dopant regions d4 are formed on the upper parts of the first and second protrusion units 210a and 210b. At this point, since the widths of the first and second protrusion units 210a and 210b are narrow, the doping concentration of the fourth dopant regions d4 can be lower than that of the third dopant region d3. In order to prevent the doping concentration difference between the fourth doped region d4 and the third doped regions d3, the upper part of the substrate 200 can be doped with the first conductive type dopant prior to forming the first oxide layer 11 (refer to FIG. 6A).

Referring to FIG. 7C, the first gate 220a having a height that is lower than the first and second protrusion units 210a and 210b is formed on the sixth oxide layer 61 between the first and second protrusion units 210a and 210b.

Referring to FIG. 7D, the sixth oxide layer 61 and the third oxide layer 31 are removed by etching using the first gate 220a as an etch mask.

Referring to FIG. 7E, a seventh oxide layer 71 is formed on the substrate 200, the first and second protrusion units 210a and 210b, and the first gate 220a. Next, the upper parts of the substrate 200 and the first and second protrusion units 210a and 210b are doped with the first conducive type dopant by using the first gate 220a as an ion injection mask. As a result, fifth dopant regions d5 are formed in the substrate 200 on both sides of the third dopant region d3, and the doping concentration of the fourth dopant region d4 increases.

Referring to FIG. 7F, a second gate 220b is formed on the seventh oxide layer 71 that covers the fifth dopant region d5 on a side of the first gate 220a, that is, beside the first protrusion unit 210a, and at the same time, a third gate 220c is formed on the seventh oxide layer 71 that covers the fifth dopant region d5 on the other side of the first gate 220a, that is, beside the second protrusion unit 210b.

Referring to FIG. 7G, the seventh oxide layer 71 is removed from the upper parts of the first and second protrusion units 210a and 210b by anisotropically etching the seventh oxide layer 71. At this point, the seventh oxide layer 71 on the first gate 220a can also be removed.

Referring to FIG. 7H, the substrate 200 is exposed by etching both Y axis direction sides of the first and second protrusion units 210a and 210b using a lithography process.

Referring to FIG. 7I, an eighth oxide layer 81 is formed on the substrate 200 that is exposed by removing of both Y axis direction sides of the first and second protrusion units 210a and 210b, on the first through third gates 220a through 220c, and on the first and second protrusion units 210a and 210b.

Next, an annealing process is performed so as to activate the third through fifth dopant regions d3 through d5. Due to the annealing, the dopants in the third through fifth dopant regions d3 through d5 are diffused. At this point, the dopants in the third and fifth dopant regions d3 and d5 diffuse into the substrate 200 under the first and second protrusion units 210a and 210b and mix with each other. The third and fifth dopant regions d3 and d5 where the dopants are activated and mixed can be a source S1, and the activated fourth regions d4 can be drains. The drain formed in the upper part of the first protrusion unit 210a is a first drain D1, and the drain formed in the upper part of the second protrusion unit 210b is a second drain D2. The annealing process can be performed in any manner after the third through fifth dopant regions d3 through d5 are formed (refer to FIG. 7E).

Referring to FIG. 7J, the upper parts of the first and second protrusion units 210a and 210b are exposed by etching the eighth oxide layer 81. Afterwards, although not shown, a bit line or bit lines that commonly contact or individually contact the first and second protrusion units 210a and 210b can be formed.

As described above, since the capacitorless DRAM according to the present invention has a vertical structure, channels can be maintained long even if the capacitorless DRAM is down scaled. Therefore, the reduction of refresh characteristics and the degradation of operational characteristics due to a short channel effect can be prevented.

Also, according to the present invention, since a capacitorless DRAM having one or two cells in an area of 4F² can be manufactured, the integration density of the capacitorless DRAM can be doubled or more when compared to the prior art.

In particular, when two channels are included in a unit cell of the capacitorless DRAM according to the present invention, reading sensing is achieved from the two channels having an identical state, thereby approximately doubling the sensing margin compared to a conventional capacitorless DRAM.

Also, the capacitorless DRAM according to the present invention can be readily manufactured using a silicon substrate instead of using an SOI substrate.

While the present invention has been particularly shown and described with reference to embodiments thereof, it should not be construed as being limited to the embodiments set forth herein but as an exemplary. It will be obvious to those of ordinary skill in this art that, for example, the roles of the source S1 and the drains D1 and D2 can be reversed, and the kind of insulating layers 11, 15, 21, 25, 31, 41, 51, 61, 71, and 81 used for manufacturing the capacitorless DRAMs according to the present invention can be changed. Therefore, the scope of the invention is defined not by the detailed description of the invention but by the appended claims.

What is claimed is:

1. A capacitorless DRAM (dynamic random access memory) comprising:
a substrate having a first dopant region formed on the upper part thereof;
a first protrusion unit formed on the substrate;
a first gate and a second gate formed on the substrate on both sides of the first protrusion unit, having a height lower than the first protrusion unit; and
an insulating material layer interposed between the substrate and the first and second gates and between the first protrusion unit and the first and second gates, wherein a second dopant region is formed on the upper part of the first protrusion unit.

2. The capacitorless DRAM of claim 1, further comprising: a second protrusion unit and a third gate sequentially formed beside the first gate which are located opposite to the first protrusion unit, and an insulating material layer interposed between the substrate and the third gate and between the second protrusion unit and the first and third gates identical to the insulating material layer interposed between the substrate and the first and second gates and between the first protrusion unit and the first and second gates,
wherein the upper part of the second protrusion unit is a dopant region identical to the second dopant region.

3. The capacitorless DRAM of claim 2, wherein the first and second protrusion units commonly contact a bit line.

4. The capacitorless DRAM of claim 2, wherein the first and second protrusion units contact different bit lines.

5. The capacitorless DRAM of claim 1, wherein the first protrusion unit has a width smaller than the first and second gates.

6. The capacitorless DRAM of claim 1, wherein one of the first and second gates is a front gate, and the other is a back gate.

7. The capacitorless DRAM of claim 2, wherein one of the first and second gates is a front gate, the other is a back gate, and the third gate is identical to the second gate.

8. The capacitorless DRAM of claim 1, wherein the substrate and the first protrusion unit are one body.

9. The capacitorless DRAM of claim 2, wherein the substrate, the first protrusion unit, and the second protrusion unit are one body.

10. A method of manufacturing a capacitorless DRAM, comprising:
forming a first protrusion unit and a second protrusion unit which are apart from each other, are parallel to each other and face each other on a substrate;
forming a first insulating layer on the substrate and the first and second protrusion units;
doping the upper part of the substrate and the upper parts of the first and second protrusion units;
forming gates having a height lower than the first and second protrusion units on the first insulating layer beside the first and second protrusion units;
removing the first insulating layer from the upper parts of the first and second protrusion units;
separating the first and second protrusion units into cell units by patterning the first and second protrusion units; and
forming a second insulating layer on the substrate exposed by the patterning of the first and second protrusion units, the gates, and the first and second protrusion units.

11. The method of claim 10, wherein the first and second insulating layers are formed of oxides.

12. The method of claim 10, wherein the forming of the first and second protrusion units comprises:
sequentially forming a first oxide layer, a first nitride layer, and a second oxide layer on a substrate;
forming a mask layer on the second oxide layer;
etching the second oxide layer, the first nitride layer, the first oxide layer, and a portion of the thickness of the substrate on both sides of the mask layer;
removing the mask layer;
forming a third oxide layer that covers the surfaces exposed by the etching on the substrate and the second oxide layer;
etching the third oxide layer and the second oxide layer until the first nitride layer is exposed;
forming a trench that exposes the substrate by removing the first nitride layer and the first oxide layer;
forming second nitride layers on inner walls of the trench;
etching the substrate using the second nitride layers as etch masks; and
removing the second nitride layers and third oxide layer.

13. The method of claim 12, further comprising doping the substrate with a dopant prior to sequentially forming the first oxide layer, the first nitride layer, and the second oxide layer.

14. The method of claim 10, further comprising exposing the upper parts of the first and second protrusion units by etching the second insulating layer after forming the second insulating layer.

15. A method of manufacturing a capacitorless DRAM, comprising:
forming first and second supporting insulating layers which are separated from each other and face each other on a substrate;
forming a first protrusion unit and a second protrusion unit respectively on the surfaces of the first and second supporting insulating layers facing each other;
forming a first insulating layer on the substrate, the first and second supporting insulating layers, and the first and second protrusion units;
firstly doping the upper part of the substrate between the first and second protrusion units and the upper parts of the first and second protrusion units;
forming a first gate having a height lower than the first and second protrusion units on the first insulating layer between the first and second protrusion units;
removing the first insulating layer and the first and second supporting insulating layers;
forming a second insulating layer on the substrate, the first and second protrusion units, and the first gate;
secondly doping the upper part of the substrate and the upper parts of the first and second protrusion units;
forming a second gate on the second insulating layer beside the first protrusion unit and forming a third gate on the second insulating layer beside the second protrusion unit;
removing the second insulating layer from the upper parts of the first and second protrusion units;
separating the first and second protrusion units into cell units by patterning the first and second protrusion units; and
forming a third insulating layer on the substrate exposed by patterning the first and second protrusion units, the first through third gates, and the first and second protrusion units.

16. The method of claim 15, wherein the forming of the first and second supporting insulating layers and the first and second protrusion units comprises:
sequentially forming a first oxide layer, a first nitride layer, and a second oxide layer on a substrate;
forming a mask layer on the second oxide layer;
etching the second oxide layer, the first nitride layer, the first oxide layer, and a portion of the thickness of the substrate on both sides of the mask layer;
removing the mask layer;
forming a third oxide layer that covers the surfaces exposed by the etching on the substrate and the second oxide layer;
etching the third oxide layer and the second oxide layer until the first nitride layer is exposed;
forming a trench that exposes the substrate by removing the first nitride layer and the first oxide layer;
forming second nitride layers on inner walls of the trench;
etching the substrate using the second nitride layers as etch masks; and
removing the second nitride layers.

17. The method of claim 16, further comprising doping the substrate prior to sequentially forming the first oxide layer, the first nitride layer, and the second oxide layer.

18. The method of claim 15, further comprising exposing the upper parts of the first and second protrusion units by etching the third insulating layer after forming the third insulating layer.

19. A method of operating a capacitorless DRAM that comprises:
a substrate having a first dopant region formed on the upper part thereof;
a first protrusion unit formed on the substrate;
a first gate and a second gate formed on the substrate on both sides of the first protrusion unit, having a height lower than the first protrusion unit; and
an insulating material layer interposed between the substrate and the first and second gates and between the first protrusion unit and the first and second gates, wherein a second dopant region is formed on the upper part of the first protrusion unit,
the method comprising applying voltages respectively to the first and second dopant regions and the first and second gates.

20. The method of claim 19, wherein the voltage is one of a data writing voltage, a data holding voltage, a data reading voltage, and a data erasing voltage.

21. The method of claim 19, wherein the capacitorless DRAM further comprises a second protrusion unit and a third gate sequentially arranged beside the first gate which are located opposite to the first protrusion unit, and an insulating material layer formed between the substrate and the third gate and between the second protrusion unit and the first and third gates identical to the insulating material layer interposed between the substrate and the first and second gates and between the first protrusion unit and the first and second gates, wherein the upper part of the second protrusion unit is a third dopant region identical to the second dopant region.

22. The method of claim 21, wherein voltages respectively are applied to the first and third dopant regions and the first and third gates.

23. The method of claim 21, wherein voltages respectively are applied to the first through third dopant regions and the first through third gates.

24. The method of claim 22, wherein the voltage is one of a data writing voltage, a data reading voltage, and a data erasing voltage.

25. The method of claim 23, wherein the voltage is one of a data writing voltage, a data reading voltage, and a data erasing voltage.

26. The method of claim 21, wherein the first and second protrusion units commonly contact a bit line.

27. The method of claim 21, wherein the first and second protrusion units individually contact bit lines different from each other.
